(19) United States
(12) Patent Application Publication
(10) Pub. No.: US 2014/0299367 A1
(43) Pub. Date: Oct. 9, 2014

(54) Component-Embedded Substrate Manufacturing Method and Component-Embedded Substrate Manufactured Using the Same

(71) Applicant: Yoshio Imamura, Ayase-shi (JP)

(72) Inventor: Yoshio Imamura, Ayase-shi (JP)

(73) Assignee: Meiko Electronics Co., Ltd., Ayase-shi, Kanagawa (JP)

(21) Appl. No.: 14/355,558

(22) PCT Filed: Nov. 8, 2011
(86) PCT No.: PCT/JP2011/075705

§ 371 Date: Apr. 30, 2014

(51) Int. Cl. H05K 13/04; H05K 1/18

(52) U.S. Cl. CPC H05K 13/0469; H05K 1/184
USPC 174/260; 29/835

(57) ABSTRACT

The method includes forming an annular seat and main marks on a metal layer simultaneously so that the annular seat opposes with a terminal of an electronic component when the component is placed above the annular seat at a subsequent step; then positioning the electronic component in a mounting expected region using the main marks and mounting the electronic component with an adhesive layer therebetween; then burying the electronic component and the main marks in an insulating substrate; then removing part of the metal layer and thereby forming first and second windows; then irradiating the adhesive layer with laser using the exposed main marks thereby forming a laser via hole; and then filling the laser via hole with copper and forming a wiring pattern from the metal layer electrically connected to the terminal through a conductive via.

### TECHNICAL FIELD

The present invention relates to a component-embedded substrate manufacturing method for embedding electrical or electronic components in a substrate and a component-embedded substrate manufactured using the same.

### BACKGROUND ART

Recently, with increased density of components mounted on the surface of an electronic circuit board, that is, enhanced functionality of the electronic circuit board, attention has been paid to a component-embedded substrate having a structure in which electronic components are embedded in an insulating substrate serving as an insulating layer. A wiring pattern is formed on the surface of the insulating substrate of the component-embedded substrate. The component-embedded substrate on the surface of which other various electronic components are mounted at a predetermined position of the wiring pattern can be used as a module board. In addition, the component-embedded substrate can also be used as a core board for use in manufacturing a component-embedded multilayer circuit board by a buildup method.

The aforementioned component-embedded substrate requires an electrical connection between the wiring pattern and the terminals of the electronic components in the insulating substrate. It has been known to use soldering for the connection (for example, see Patent Document 1).

In the meantime, several surface mounting processes of various electronic components are performed in the process of manufacturing the module board or the multilayer circuit board. In general, reflow soldering is performed for the surface mounting of the electronic components. Each time an electronic component is mounted on the surface, the component-embedded substrate is placed in a reflow furnace and is heated to a temperature at which the solder melts. Therefore, the connection portions inside the insulating substrate in the component-embedded substrate disclosed in Patent Document 1 are heated to a solder melting temperature several times, which may reduce the reliability of the connection portions.

In light of this, in order to improve the reliability of the connection portions in the component-embedded substrate, it has been known to provide electrical connections between the connection portions inside the insulating substrate by copper plating instead of solder plating (for example, see Patent Document 2). Specifically, the melting point of the copper is higher than the melting point of the solder, and thus the component-embedded substrate placed in the reflow furnace does not allow the connection portions to melt, thereby maintaining the reliability of the connection portions.

The detail of the manufacture method disclosed in Patent Document 2 is described below.

First, a lamellar body is formed by laminating an insulating layer on a metal layer such as a copper foil. Then, a guide hole is formed in the lamellar body, and further a connection hole is formed in the lamellar body using the guide hole as a reference. The connection hole is formed in an intra-substrate component region to be arranged on the insulating layer. In a later step, copper is filled in the connection hole. The filled copper forms a metal joint for electrically connecting the wiring pattern to the terminal of the intra-substrate component. Subsequently, an adhesive is applied to the region and the adhesive is used to fix the intra-substrate component on the insulating layer. At this time, the intra-substrate component is positioned using the connection hole. Here, the intra-substrate component is positioned so that the terminal thereof corresponds to the connection hole. Note that the adhesive flows into the connection hole.

Then, an insulating base material such as a prepreg to serve as the insulating substrate is laminated on the insulating layer of the lamellar body. At this point, the insulating substrate having the intra-substrate component buried in the insulating base material is formed. The obtained insulating substrate has the metal layer of the lamellar body located on one surface thereof and the connection hole is opened in an outer surface of the metal layer. In this state of the insulating substrate, the adhesive inside the connection hole is removed from the outer surface side of the metal layer to expose the terminal of the intra-substrate component inside the connection hole. Then, the entire outer surface of the metal layer including the connection hole is subjected to a copper plating process. This causes copper to grow and fill the connection hole so as to electrically connect the metal layer positioned on the surface of the insulating substrate to the terminal of the intra-substrate component. Subsequently, part of the metal layer on the surface of the insulating substrate is etched to form a wiring pattern and thereby to form a component-embedded substrate.

### PRIOR-ART DOCUMENT

### Patent Documents

Patent Document 1: Japanese Patent Laid-Open No. 2010-027917
Patent Document 2: National Publication of International Patent Application No. 2008-522396

### SUMMARY OF THE INVENTION

### Problem to be Solved by the Invention

Unfortunately, the aforementioned manufacturing method has a problem that when the adhesive for fixing the intra-substrate component is applied to the region, part of the adhesive flows into the connection hole as described above, resulting in reduction in thickness of the adhesive layer, which may cause the following troubles.

First, a commonly used adhesive contains a filler to maintain the strength of the adhesive layer after the adhesive is cured. However, an adhesive layer with a thickness less than the size of the filler may cause the filler to easily fall off from the adhesive layer and hence a required strength may not be obtained.

Note that the adhesive layer is also used as the insulating layer. Thus, when the adhesive layer is too thin, it may be difficult to ensure the required insulating properties.

Therefore, a low viscosity adhesive or a low thixotropy adhesive which tends to flow into the connection hole is not suitable for the aforementioned manufacturing method, and hence the available adhesive is limited.

It is an object of the invention, which has been made in view of the above circumstances, to provide a component-embedded substrate manufacturing method capable of positioning and forming a connection hole for use in electrically connecting a terminal of an embedded component to a wiring pattern with a good accuracy and widening the range of choice of an adhesive for fixing the component; and a component-embedded substrate manufactured using the same.

### Means for Solving the Problem

In order to attain the above object, the present invention provides a method of manufacturing a component-embedded substrate which includes an electrical or electronic component embedded in an insulating substrate having a wiring pattern on a surface thereof and in which a terminal of the component is electrically connected to the wiring pattern, the method comprising: a metal layer forming step of forming a metal layer on a support plate, the metal layer including a first surface contacting the support plate and a second surface opposite to the first surface, and the second surface having a mounting expected region for the component and a non-mounting region other than the mounting expected region; a mark forming step of forming a metal main mark in the non-mounting region of the second surface; a seat forming step of forming a metal seat in the mounting expected region of the second surface simultaneously with the formation of the main mark, the metal seat having a central through-hole; an adhesive applying step of applying an insulating adhesive to the mounting expected region and the seat to thereby form an adhesive layer, the adhesive layer having a filling region in a position of the central through-hole of the seat, and the filling region filling the inside of the central through-hole with the adhesive; a component mounting step of mounting the component on the adhesive layer in a state in which the component is positioned using the main mark as a reference and the terminal of the component contacts the filling region; a buried layer forming step of forming a buried layer serving as the insulating substrate for burying the component and the main mark on the second surface; a separation step of separating the support plate from the metal layer to expose the first surface of the metal layer by the separation thereof; a window forming step of removing part of the metal layer from the exposed first surface side and thereby forming a first window for exposing at least the main mark and a second window for exposing at least the central through-hole of the seat respectively in the metal layer; a via hole forming step of determining the position of the terminal of the component using the exposed main mark as a reference, removing the adhesive of the filling region filling the inside of the through-hole of the exposed seat, and thereby forming a via hole reaching the terminal in the filling region; a conductive via forming step of subjecting the via hole to a plating process, then filling metal in the via hole and the second window, and thereby forming a conductive via for electrically connecting between the terminal and the metal layer; and a pattern forming step of forming the metal layer into the wiring pattern.

Here, a preferred aspect of the component-embedded substrate manufacturing method is that in the mark forming step, a metal sub mark in a non-mounting region of the second surface is formed simultaneously with the main mark; between the separation step and the window forming step, the method further comprises a through-hole mark forming step of determining the sub mark using X-rays and thereby forming a through-hole mark penetrating all of the metal layer, the sub mark, and the buried layer; and in the window forming step, the first window and the second window are formed using the through-hole mark as a reference.

In addition, a preferred aspect is that the main mark, the sub mark, and the seat are formed by pattern plating using a plating resist film.

In addition, the present invention provides a component-embedded substrate manufactured using the above described component-embedded substrate manufacturing method.

Here, a preferred aspect is that the component-embedded substrate further comprises the sub mark and the through-hole mark.

### Effects of the Invention

According to the component-embedded substrate manufacturing method of the present invention, the electrical or electronic component is positioned using the main mark formed on the metal layer; and the via hole formed in a later step is formed by removing resin inside the central through-hole of the seat formed simultaneously with the main mark. In other words, the position of the formed via hole is the same as that of the central through-hole of the seat. Accordingly, the position of the component determined using the main mark formed simultaneously with the seat is the same as the position determined using the seat, that is, the via hole. Thus, the via hole for electrically connecting the component to the terminal of the component can be positioned with extremely high accuracy.

In addition, according to the present invention, the seat formed simultaneously with the main mark serves as a spacer for ensuring a space between the component and the metal layer (wiring pattern), and hence can maintain a constant thickness of the adhesive layer between the component and the metal layer. As a result, an adhesive layer having excellent adhesive strength and insulating properties can be stably obtained. Moreover, the seat has a central through-hole, and the position of the central through-hole matches the position of the terminal of the component to be mounted. Thus, the via hole can be formed at the exact position as designed by removing the filling region of the adhesive layer inside the central through-hole.

In addition, according to the component-embedded substrate manufacturing method of the present invention, the component is mounted on the metal layer with an adhesive interposed therebetween and then the adhesive is cured to obtain the adhesive layer. The metal layer does not have a hole to be preliminarily drilled therein, which prevents uncured adhesive from falling down in the hole. This enables the obtained adhesive layer to have a required thickness and can ensure the adhesive strength and the insulating properties as designed. In other words, the present invention widens the range of choice of the adhesive.

Further, according to the present invention, the mark forming step forms the sub mark simultaneously with the main mark; and before the window forming step, the method comprises a through-hole mark forming step of determining the sub mark using X-rays and thereby forming a through-hole mark penetrating all of the metal layer, the sub mark, and the buried layer. If the through-hole mark is used as a reference, the position of the main mark hidden in the metal layer and the position corresponding to the terminal of the component can be easily determined, and hence the first window and the second window can be easily formed.

In addition, according to the present invention, the main mark, the sub mark, and the seat are formed by pattern plating using a plating resist film, and thus can be easily formed in a printed circuit board manufacturing facility which has been commonly used heretofore. Therefore, the present invention contributes to improving production efficiency of the entire component-embedded substrate.

In addition, the component-embedded substrate of the present invention is obtained by the above described manufacturing method and hence has an extremely high accuracy of positioning between the embedded component and the wiring pattern and a low rate of occurrence of defective products.

### BRIEF DESCRIPTION OF THE DRAWINGS

FIG. 1 is a cross-sectional view schematically illustrating a procedure for forming a mark and a seat on a metal layer of a support plate in a component-embedded substrate manufacturing method according to an embodiment of the present invention.

FIG. 2 is a perspective view schematically illustrating the seat of FIG. 2.

FIG. 3 is a cross-sectional view schematically illustrating a state in which an adhesive is supplied to the metal layer of FIG. 1(e).

FIG. 4 is a cross-sectional view schematically illustrating a state in which an electronic component is mounted on the adhesive of FIG. 3.

FIG. 5 is a cross-sectional view schematically illustrating a state in which an insulating base material and a copper foil are laminated on the metal layer on which the electronic component is mounted.

FIG. 6 is a cross-sectional view schematically illustrating a state in which the insulating base material and the copper foil are laminated and integrated on the metal layer on which the electronic component is mounted.

FIG. 7 is a cross-sectional view schematically illustrating a state in which the support plate is separated from the metal layer.

FIG. 8 is a cross-sectional view schematically illustrating a state in which an X-ray drilling process is applied to an intermediate.

FIG. 9 is a cross-sectional view schematically illustrating a state in which windows are formed in the intermediate of FIG. 8.

FIG. 10 is a cross-sectional view schematically illustrating a state in which laser via holes are formed in the intermediate of FIG. 9.

FIG. 11 is a cross-sectional view schematically illustrating a state in which the intermediate of FIG. 9 is irradiated with laser.

FIG. 12 is a cross-sectional view schematically illustrating a state in which a plating process is applied to the intermediate of FIG. 10.

FIG. 13 is a cross-sectional view schematically illustrating the component-embedded substrate according to an embodiment of the present invention.

### DESCRIPTION OF EMBODIMENTS

There follows a description of a procedure for manufacturing a component-embedded substrate having an electronic component (hereinafter referred to as an intra-substrate component) 14 embedded in an insulating substrate by applying a component-embedded substrate manufacturing method of the present invention thereto.

According to the present invention, first, a metal layer is formed on a support plate (metal layer forming step).

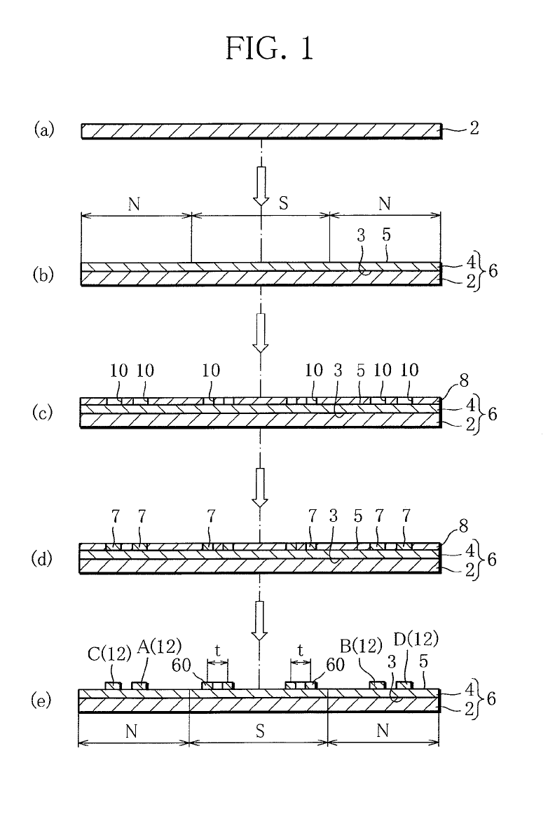

As illustrated in FIG. 1(a), the present step prepares a support plate 2. The support plate 2 is, for example, a thin plate made of stainless steel. Then, as illustrated in FIG. 1(b), a first metal layer 4 made of a thin film is formed on the support plate 2. The first metal layer 4 is made of, for example, a copper plating film obtained by electroplating. Thus, a copper-clad steel plate 6 is obtained. Here, a surface of the first metal layer 4 contacting the support plate 2 is assumed to be a first surface 3; and a surface opposite to the first surface 3 is assumed to be a second surface 5. In addition, the second surface 5 has a mounting expected region S for the intra-substrate component 14 and non-mounting regions N other than the mounting expected region.

Next, a seat made of a copper annular body is formed simultaneously with the mark forming step of forming a positioning mark made of a copper columnar body on the copper-clad steel plate 6 (seat forming step).

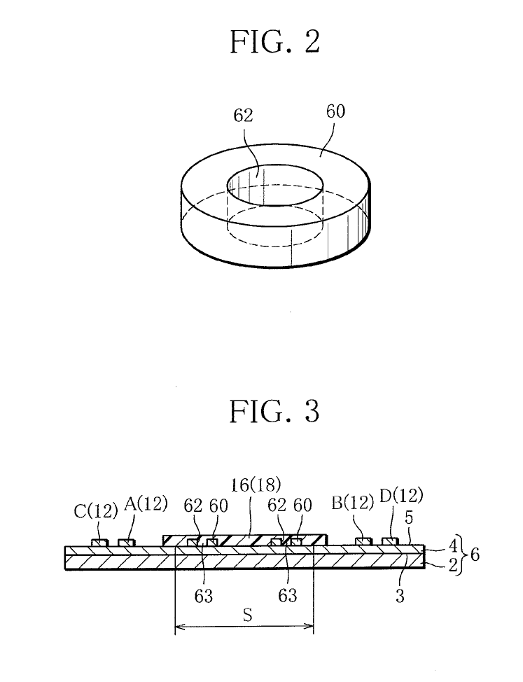

More particularly, as illustrated in FIG. 1(c), a mask layer 8 is formed on the first metal layer 4 of the prepared copper-clad steel plate 6. The mask layer 8 is, for example, a plating resist made of a dry film having a predetermined thickness. An opening 10 having a predetermined shape is provided at a predetermined position and the metal layer 4 is exposed from the opening 10. Then, the copper-clad steel plate 6 having such mask layers 8 is subjected to copper electroplating to preferentially deposit copper 7 in the exposed portion (FIG. 1(d)). Subsequently, the dry film serving as the mask layer 8 is removed to form a copper post at a predetermined position on the second surface 5 of the first metal layer 4 (FIG. 1(e)). As the copper posts, cylindrical positioning marks 12 and annular seats 60 are formed. Here, particularly as illustrated in FIG. 2, the seat 60 has a shape having a central through-hole 62 at a center of a flat cylindrical body. Note that the copper posts are formed as high as the dry film, and the height of at least the seat 60 is set to the same size as the thickness of the adhesive layer 18 expected to be formed in a later step.

The position of arranging the mark 12 can be arbitrarily selected in a non-mounting region N, but preferably is a position that can be easily recognized by an optical sensor of an optical positioning apparatus (unillustrated) for positioning the intra-substrate component 14 to be embedded in the insulating substrate. According to the present embodiment, as illustrated in FIG. 1(e), the marks 12 are formed, two for each, in the non-mounting region N of both end portions of the copper-clad steel plate 6 so as to sandwich the mounting expected region S on which the intra-substrate component 14 is expected to be mounted. Here, of the marks in FIG. 1(e), the marks located near the mounting expected region S are referred to as inside marks (main marks) A and B, and the marks located opposite to the mounting expected region S with the inside marks A and B therebetween are referred to as outside marks (sub marks) C and D.

Meanwhile, the positions of arranging the seats 60 each are set to a terminal position t which is inside the mounting expected region S and at which the terminal 20 of the intra-substrate component 14 is to be positioned so that the central through-holes 62 face each other.

Next, the adhesive 16 is supplied to the mounting expected region S (adhesive applying step).

First, as illustrated in FIG. 3, the adhesive 16 to serve as an insulating adhesive layer is supplied to the component mounting expected region S on the metal layer 4. At this time, the embodiment of the adhesive 16 to be supplied is not particularly limited, but may be an embodiment of applying a paste adhesive 16 having a low viscosity or a high viscosity with a predetermined thickness. The present embodiment uses the low-viscosity adhesive 16, and as illustrated in FIG. 3, the adhesive 16 is applied to a thickness just enough to slightly cover the seat 60 and to cover the entire mounting expected region S. Here, the adhesive 16 is also introduced into the central through-hole 62 of the seat 60 and the central through-hole 62 is assumed to be in a state of being filled with the adhesive 16. Thus, the adhesive layer has the filling region 63 for filling the inside of the central through-hole 62 with the adhesive.

As is clear from FIG. 3, one end (lower side in FIG. 3) of the central through-hole 62 is blocked by the metal layer 4 and hence the adhesive 16 remains in the central through-hole 62. Here, the adhesive 16 may cover the entire mounting expected region S, and the accuracy of positioning the adhesive 16 may be relatively low. Note that it is preferable that when the adhesive 16 is positioned, the mounting expected region S is determined using the inside marks A and B as the references and the adhesive 16 is applied to the determined position, which increases the accuracy of positioning the adhesive 16.

The above described adhesive 16 is cured to be an adhesive layer 18 with a predetermined thickness. The obtained adhesive layer 18 fixes the intra-substrate component 14 in a predetermined position and has predetermined insulating properties. The adhesive 16 is not particularly limited as long as the adhesive exhibits a predetermined adhesive strength and predetermined insulating properties after it is cured, but the examples thereof include an adhesive having a filler added to a ultraviolet curable epoxy-based resin or polyimide-based resin, an adhesive having a filler added to a thermosetting epoxy-based resin or polyimide-based resin, and the like. Examples of the filler include a fine powder such as silica (silicon dioxide) and a glass fiber. The present embodiment uses a low-viscosity adhesive having a fine powder of silica added to a thermosetting epoxy-based resin.

Next, the intra-substrate component 14 is mounted on the copper-clad steel plate 6 with the adhesive 16 interposed therebetween (component mounting step).

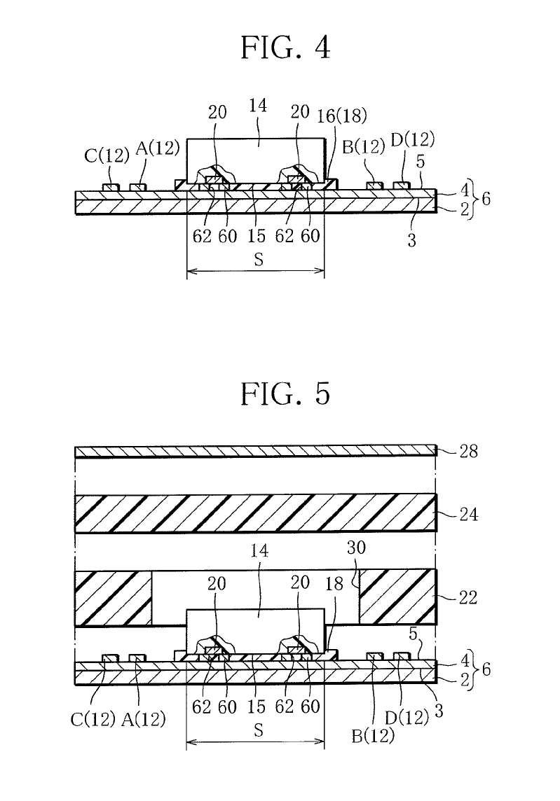

First, as illustrated in FIG. 4, the intra-substrate component 14 is mounted on the adhesive 16 applied to the mounting expected region S. Here, as is clear from FIG. 4, the intra-substrate component 14 is a rectangular packaging component in which IC chips and the like (unillustrated) are covered with resin and a plurality of terminals 20 are provided in a lower portion of the packaging component. The intra-substrate component 14 is positioned in the mounting expected region S using the inside marks A and B as the references. More particularly, the intra-substrate component 14 is positioned at a position in which the terminal 20 of the intra-substrate component 14 faces the central through-hole 62 of the seat 60 and the terminal 20 contacts the filling region 63. Then, the intra-substrate component 14 is pressed toward the first metal layer 4 and the lower surface 15 thereof abuts the upper end portion of the seat 60. This secures a predetermined thickness of space between the second surface 5 of the first metal layer 4 and the lower surface 15 of the intra-substrate component 14. Subsequently, the adhesive 16 is heated to a predetermined temperature until it is cured to be an adhesive layer 18. Thus, the adhesive layer 18 has the thickness as designed, thus securing required adhesive strength and insulating properties. As a result, the intra-substrate component 14 is fixed to a predetermined position.

Next, insulating base materials are laminated to bury the intra-substrate component 14, the inside marks A and B, and the outside marks C and D (buried layer forming step).

First, as illustrated in FIG. 5, insulating base materials 22 and 24 are prepared. Both of the insulating base materials 22 and 24 are made of resin. Here, a sheet-like so-called prepreg obtained by impregnating a glass fiber with an uncured-state thermosetting resin is preferably used for the insulating base materials 22 and 24. The insulating base material 22 has a through-hole 30. The through-hole 30 is formed to have a size allowing the intra-substrate component 14 to be inserted thereinto. Then, the insulating base material 22 is laminated on the first metal layer 4 so as to insert the intra-substrate component 14 into the through-hole 30; then the insulating base material 24 is placed on an upper side thereof; and further a copper foil to serve as the second metal layer 28 is placed on an upper side thereof; and then the entire layer is subjected to hot pressing.

Thereby, the uncured-state thermosetting resin of the prepreg is pressurized and filled in a gap of the through-hole 30 and the like, and then is cured by the heat of the hot pressing. As a result, as illustrated in FIG. 6, an insulating substrate 34 including the insulating base materials 22 and 24 is formed and the intra-substrate component 14 is buried in the insulating substrate 34. Here, the through-hole 30 is preliminarily provided in the insulating base material 22 (see FIG. 5), which can alleviate the pressure applied to the intra-substrate component 14 during hot pressing. Therefore, even a large-sized intra-substrate component 14 can be buried in the insulating substrate.

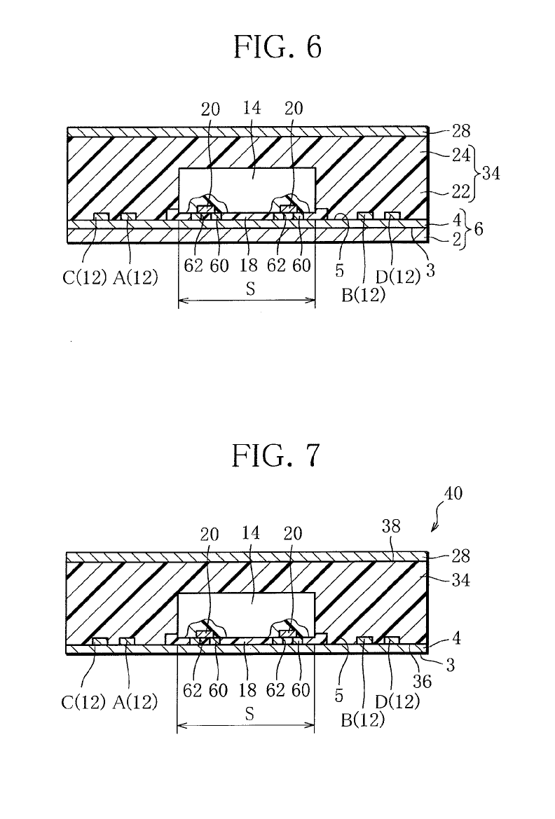

Then, as illustrated in FIG. 7, the support plate 2 is separated (separation step).

The present step separates the support plate 2 from the first metal layer 4 to expose the first surface 3 of the first metal layer 4 by the separation. Thus, an intermediate 40 of the component-embedded substrate is obtained. The intermediate 40 includes the insulating substrate 34 having the intra-substrate component 14 therein; the first metal layer 4 formed on one surface (lower surface) 36 of the insulating substrate 34; and the second metal layer 28 formed on the other surface (upper surface) 38 thereof.

Next, windows are formed in the obtained intermediate 40 by removing a predetermined portion of the first metal layer 4 (window forming step).

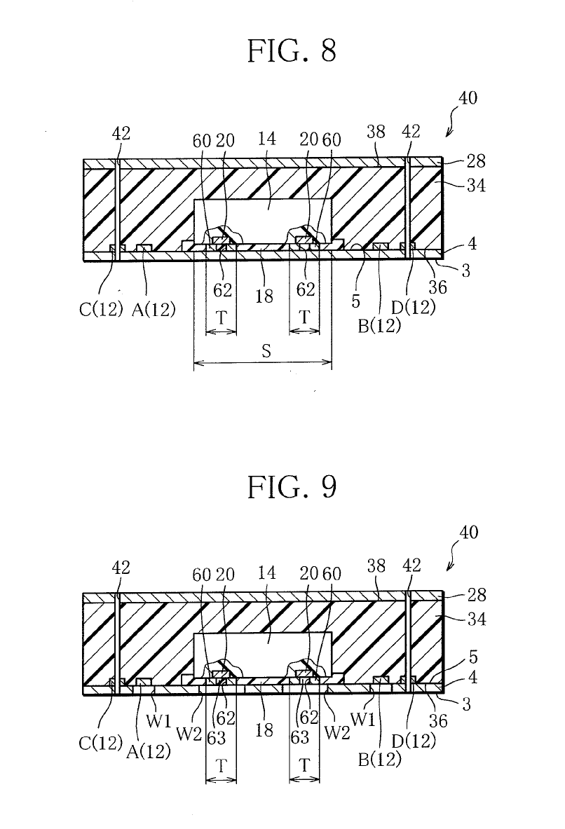

First, as illustrated in FIG. 8, the positions of the outside marks C and D are detected and a drill is used to form reference holes (through-hole marks) 42 and 42 each penetrating all of both of the metal layers 4 and 28, the insulating substrate 34, and the outside marks C and D. Here, the positions of the outside marks C and D are detected by an X-ray irradiation apparatus (unillustrated) for use in a common X-ray drilling process.

Subsequently, the reference holes 42 are used as the references to determine a portion in which the inside marks A and B are located and a portion in which the seats 60 are located (hereinafter referred to as a seat location portion) T. Then, for each determined portion, part of the first metal layer 4 is removed from the first surface 3 of the first metal layer 4 by a commonly used etching process. This forms a first window W1 for exposing part of the insulating substrate 34 together with the inside marks A and B; and a second window W2 for exposing a portion of the adhesive layer 18 including the seat location portion T. At this time, as illustrated in FIG. 9, the first window W1 is formed slightly larger than the inside marks A and B. Thus, the entire inside marks A and B can be easily recognized through the first window W1. Meanwhile, in the case of the second window W2, the filling region 63 of the central through-hole 62 of the seat 60 needs to be completely exposed but the entire seat 60 does not need to be exposed. Note that the present embodiment forms both of the first window W1 and the second window W2 to be relatively large enough to expose the entire inside marks A and B and the entire seat 60. This does not need to increase the positioning accuracy when the windows are formed and hence preferably contributes to improving the production efficiency thereof.

Next, the filling region 63 of the adhesive layer 18 inside the central through-hole 62 of the seat 60 is removed to form a via hole in the filling region 63 (via hole forming step).

First, the exposed inside marks A and B are recognized by an optical sensor of an optical positioning apparatus (unillustrated). Then, the positions of the inside marks A and B are used as the references to determine the position of the terminal 20 of the intra-substrate component 14 hidden in the adhesive layer 18. Subsequently, the determined terminal position is irradiated with laser such as carbon dioxide laser to remove the filling region 63 of the adhesive layer 18 so as to expose the terminal 20 of the intra-substrate component 14. The laser is emitted in a certain width of irradiation range R and can remove the adhesive layer 18 in the irradiation range R.

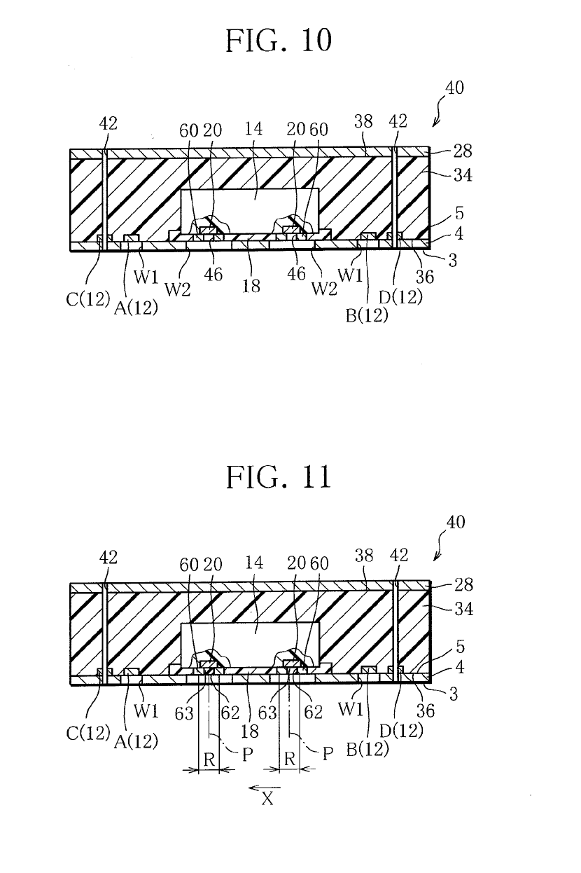

According to the present invention, the position of the terminal 20 of the intra-substrate component 14 matches that of the central through-hole 62 of the seat 60, and hence the laser is emitted to the lower end surface of the seat 60 including the central through-hole 62. This removes the filling region 63 of the adhesive layer 18 inside the central through-hole 62, resulting in that the central through-hole 62 is formed into a laser via hole (hereinafter referred to as an LVH) 46 reaching the terminal 20 (FIG. 10). Here, the central through-hole 62 of the seat 60 and the terminal 20 of the intra-substrate component 14 are accurately positioned in advance. Thus, the LVH 46 can be formed at the exact position as designed by removing the filling region 63 of the adhesive layer 18 inside the central through-hole 62. Here, according to the present invention, even if the laser irradiation range R is shifted a little as illustrated by an arrow X in FIG. 11, the metal seat 60 serves as a mask to prevent the adhesive layer 18 other than the preset portion from being removed. Thus, the filling region 63 of the adhesive layer 18 inside the central through-hole 62 can be preferentially removed. Therefore, the present invention can more stably form the LVH 46 at an accurate position. Note that the one-dot chain line indicated by the reference character P in FIG. 11 represents the central axis line of the laser irradiation range.

As is clear from the above described embodiment, the present invention is characterized in that the inside marks A and B are used not only to position the intra-substrate component 14 but also to form the LVH 46 again. Thus, the present invention can exhibit an extremely high accuracy of positioning and hence can form the LVH 46 at an accurate position relative to the terminal 20 hidden in the adhesive layer 18.

Next, a plating process is applied to the intermediate 40 in which the LVH 46 is formed, and then copper is filled in the LVH 46 to form a conductive via for electrically connecting between the terminal 20 of the intra-substrate component 14 and the first metal layer 4 (conductive via forming step).

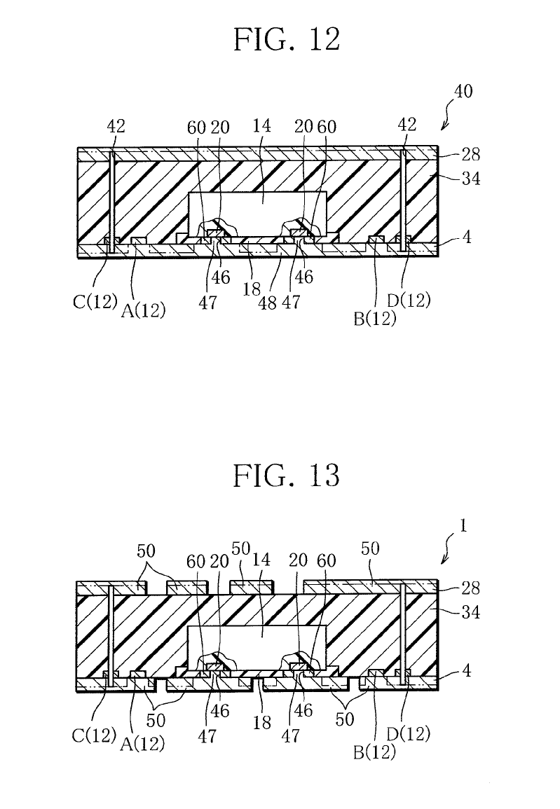

First, a copper electroless plating process is applied to the inside of the first window W1 and the second window W2 including the inside of the LVH 46. Thereby, the surfaces of the insulating substrate 34 and the adhesive layer 18 partially exposed through the first window W1 and the second window W2, the inner wall surface of the LVH 46, and the surface of the terminal 20 of the intra-substrate component 14 are covered with copper. Subsequently, a copper electroplating process is applied to grow a copper plating layer 48 covering the entire first metal layer 4 including the inside of the LVH 46 as illustrated in FIG. 12. Thus, the inside of the LVH 46 is filled with copper to form a conductive via 47. The conductive via 47 is integrated into the first metal layer 4 so that the terminal 20 of the intra-substrate component 14 is electrically connected to the first metal layer 4.

Next, parts of the first metal layer 4 and the second metal layer 28 on the surface of the insulating substrate 34 are removed to form a predetermined wiring pattern 50 (pattern forming step).

The parts of both of the metal layers 4 and 28 are removed by a common etching process. This forms a component-embedded substrate 1 incorporating the intra-substrate component 14 having the terminal 20 electrically connected to the wiring pattern 50 in the insulating substrate 34 having the predetermined wiring pattern 50 on the surface thereof as illustrated in FIG. 13.

The present invention does not preliminarily drill a hole in the metal layer 4 of the mounting expected region S and hence prevents the adhesive from falling down to the lower side of the metal layer 4. Therefore, various adhesives including low-viscosity adhesives can be used.

Thus obtained component-embedded substrate 1 can be used as a module board by mounting other electronic components on the surface thereof. In addition, the component-embedded substrate 1 can also be used as a core board to form a multilayer circuit board by a commonly used buildup method.

Note that the above described embodiments use both of the inside mark A and the inside mark B as the marks for positioning the intra-substrate component 14 and the LVH, but the present invention is not limited to these embodiments. For example, another embodiment may use only one of the inside mark A and the inside mark B as the marks for positioning the intra-substrate component 14 and the LVH. The present invention is characterized by using the same mark to determine the terminal position when the intra-substrate component is positioned and the LVH is provided, and hence even the use of only one of the inside mark A and the inside mark B can exert sufficiently high positioning accuracy. The above description has focused on embodiments using both of the inside mark A and the inside mark B as preferred embodiments of more improving the positioning accuracy.

Note that the present invention is not limited to the embodiments of providing the positioning marks near the mounting expected region S, but the positioning marks may be provided at a portion far away from the mounting expected region S. For example, the embodiment of providing the positioning mark at a portion far away from the mounting expected region S is used when a plurality of component-embedded substrates (pieces) are made in a large-size workpiece. More particularly, the workpiece is a substrate having a large frame portion on a peripheral thereof and a plurality of sheets are formed inside the large frame portion. Each sheet has a small frame portion on a peripheral thereof and a plurality of pieces are formed inside the small frame portion. Finally, each piece is cut away to obtain an individual component-embedded substrate. In such a workpiece, for example, the main mark (inside mark) is formed in the small frame portion and the sub mark (outside mark) is formed in the large frame portion. As described above, in the large-size workpiece, the main mark and the sub mark (positioning mark) are formed at a portion far away from the piece (mounting expected region S) such as the large frame portion and the small frame portion described above; and these marks are used as the references to determine the position of the component and the position of the terminal when the LVH is provided.

Note that the component embedded in the insulating substrate is not limited to the packaging component, but the present invention may embed other various electronic components such as chip components.

### EXPLANATION OF REFERENCE CHARACTERS

1 component-embedded substrate
2 support plate
3 first surface
4 first metal layer
5 second surface
6 copper-clad steel plate
8 mask layer
12 mark
14 electronic component (intra-substrate component)
16 adhesive
18 adhesive layer
20 terminal
34 insulating substrate
40 intermediate
46 laser via hole (LVH)
47 conductive via
50 wiring pattern
60 seat
63 filling region
N non-mounting region
S mounting expected region

1. A component-embedded substrate manufacturing method of manufacturing a component-embedded substrate which includes an electrical or electronic component embedded in an insulating substrate having a wiring pattern on a surface thereof and in which a terminal of the component is electrically connected to the wiring pattern, the method comprising:
a metal layer forming step of forming a metal layer on a support plate, the metal layer including a first surface contacting the support plate and a second surface opposite to the first surface, and the second surface having a mounting expected region for the component and a non-mounting region other than the mounting expected region;
a mark forming step of forming a metal main mark in the non-mounting region of the second surface;
a seat forming step of forming a metal seat in the mounting expected region of the second surface simultaneously with the formation of the main mark, the metal seat having a central through-hole;
an adhesive applying step of applying an insulating adhesive to the mounting expected region and the seat to thereby form an adhesive layer, the adhesive layer having a filling region in a position of the central through-hole of the seat, and the filling region filling the inside of the central through-hole with the adhesive;
a component mounting step of mounting the component on the adhesive layer in a state in which the component is positioned using the main mark as a reference and the terminal of the component contacts the filling region;
a buried layer forming step of forming a buried layer serving as the insulating substrate for burying the component and the main mark on the second surface;
a separation step of separating the support plate from the metal layer to expose the first surface of the metal layer by the separation thereof;
a window forming step of removing part of the metal layer from the exposed first surface side to form a first window for exposing at least the main mark and a second window for exposing at least the central through-hole of the seat respectively in the metal layer;
a via hole forming step of determining the position of the terminal of the component using the exposed main mark as a reference, removing the adhesive of the filling region filling the inside of the through-hole of the exposed seat, and thereby forming a via hole reaching the terminal in the filling region;
a conductive via forming step of subjecting the via hole to a plating process, then filling metal in the via hole and the second window, and thereby forming a conductive via for electrically connecting between the terminal and the metal layer; and
a pattern forming step of forming the metal layer into the wiring pattern.

2. The component-embedded substrate manufacturing method according to claim 1, wherein
in the mark forming step, a metal sub mark in a non-mounting region of the second surface is formed simultaneously with the main mark;
between the separation step and the window forming step, the method further comprises a through-hole mark forming step of determining the sub mark using X-rays and forming a through-hole mark penetrating all of the metal layer, the sub mark, and the buried layer; and
in the window forming step, the first window and the second window are formed using the through-hole mark as a reference.

3. The component-embedded substrate manufacturing method according to claim 1, wherein the main mark, the sub mark, and the seat are formed by pattern plating using a plating resist film.

4. A component-embedded substrate manufactured using the component-embedded substrate manufacturing method according to claim 1.

5. The component-embedded substrate according to claim 4, further comprising a metal sub mark formed in a non-mounting region of the second surface simultaneously with the main mark, and a through-hole mark formed by determining the sub mark using X-rays, so as to penetrate all of the metal layer, the sub mark, and the buried layer.

6. The component-embedded substrate manufacturing method according to claim 2, wherein the main mark, the sub mark, and the seat are formed by pattern plating using a plating resist film.
